(19) United States
(12) Patent Application Publication
(10) Pub. No.: US 2026/0191036 A1
(43) Pub. Date: Jul. 2, 2026

(54) SEMICONDUCTOR DEVICE AND METHOD FOR FABRICATING THE SAME

(71) Applicant: Intel Corporation, Santa Clara, CA (US)

(72) Inventors: Jieping ZHANG, Mesa, AZ (US); Xiang LI, Portland, OR (US); Ravindranath Vithal MAHAJAN, Chandler, AZ (US); Derchang KAU, Cupertino, CA (US); Xiaorong XIONG, Chandler, AZ (US)

(21) Appl. No.: 19/002,854

(22) Filed: Dec. 27, 2024

(51) Int. Cl. H01L 23/538; H01L 23/00; H01L 23/14; H01L 25/07; H10B 80/00

(52) U.S. Cl. CPC H10W 70/611; H10W 90/00; H10W 90/401; H10B 80/00; H10W 70/698; H10W 72/01257; H10W 72/01357; H10W 72/072; H10W 72/073; H10W 72/07331; H10W 72/227; H10W 72/241; H10W 72/248; H10W 72/856; H10W 90/24; H10W 90/297; H10W 90/722; H10W 90/724; H10W 90/732; H10W 99/00

(57) ABSTRACT

A semiconductor device and a method for fabricating a semiconductor device are described. The semiconductor device includes (i) a first passive die and a first core die arranged-side-by-side laterally into a first tier; (ii) a second core die arranged into a second tier vertically on the first tier, the first core die including a first top metallization layer on a top of the first core die and a first bottom metallization layer on a bottom of the first core die, the second core die including a second top metallization layer on a top of the second core die and a second bottom metallization layer on a first portion of a bottom of the second core die; (iii) one or more first bumps disposed between a second portion of the bottom of the second core die to couple the second core die and the first passive die.

### BACKGROUND

The escalating need for data processing power necessitates the ability to perform more computations in a smaller space while consuming less energy. In traditional two-dimensional (2D) chip designs, enhancing processing capabilities typically requires expanding the chip's size and energy consumption. However, three-dimensional (3D) designs, also known as vertical integration, have become an effective alternative. These 3D packaging structures enhance the number of functions per unit area while maintaining or even reducing energy usage, all within the same or a reduced footprint. Consequently, electronic devices can be packaged more compactly. A 3D integrated circuit (3DIC) is created by stacking various chips or wafers on top of one another within a single enclosure. The individual chips within this enclosure are linked through methods such as through-silicon vias (TSVs) and micro-bumps or through hybrid bonding technologies.

However, as the need for high performance computing grows, so does the number of layers in 3D packaging. For example, the bandwidth and storage capacity demand for computer memory (e.g., high bandwidth memory is anticipated to grow by two to threefold with each new generation. Due to these escalating requirements, the number of memory layers is expected to reach a high of 12 or even extend up to 16 layers (or tiers). However, given the current technologies for die thinning and bumping processes, the stack up of the TSV dies and memory dies can have height variations that cause co-planarity issues. Such height variations and co-planarity issues can accumulate as more tiers are stacked, and also increase the possibility of lacking proper bonding, die cracking, open joins and bridge joints. Additionally, the material used for coupling the dies in such a stacked memory structure is not designed for dissipating heat thus affecting the thermal performance of the stacked memory especially when more tiers are stacked.

Therefore, there is a need for an improved semiconductor device (e.g., memory unit, logic chip unit, or a combination thereof) with additional thermal conductive layers between the dies of a stacked memory structure and a method for fabricating the same to address the issues, more particularly, to facilitate heat dissipation and enhance thermal envelope for stacked memory dies coupled to TSVs dies to build a high bandwidth memory.

### BRIEF DESCRIPTION OF THE DRAWINGS

The accompanying drawings serve to provide an understanding of non-limiting aspects. Further non-limiting aspects and many of the intended advantages will become apparent directly from the following detailed description. The elements and structures shown in the drawings are not necessarily shown to scale relative to each other. Like reference numerals refer to like or corresponding elements and structures. Non-limiting aspects described herein will be better understood by one of ordinary skill in the art from the following detailed description and in conjunction with the drawings, in which:

FIG. 1 shows a schematic diagram illustrating a cross-sectional view of a 3D packaging structure.

FIG. 2A shows a schematic diagram illustrating a non-limiting semiconductor device according to various aspects described herein.

FIG. 2B shows a schematic diagram illustrating another non-limiting semiconductor device according to various aspects described herein.

FIGS. 3A-3C show schematic diagrams illustrating non-limiting core dies according to various aspects described herein.

FIG. 4 shows a flow chart illustrating a method for fabricating a semiconductor device according to various non-limiting aspects described herein.

FIGS. 5A and 5B show flow charts illustrating processes of a step of the method of FIG. 4 according to a non-limiting aspect described herein.

FIG. 6 shows a flow chart illustrating a step of the method of FIG. 4 according to a non-limiting aspect described herein.

FIG. 7 shows a schematic diagram illustrating a process of preparing a core die according to a non-limiting aspect described herein.

FIG. 8 shows a schematic diagram illustrating a process of fabricating a semiconductor device according to a non-limiting aspect described herein.

### DETAILED DESCRIPTION

Aspects described below in the context of a method are analogously valid for the respective element, device, apparatus, or system, and vice versa. Furthermore, it will be understood that the aspects described below may be combined, for example, a part of one aspect may be combined with a part of another aspect, and a part of one aspect may be combined with a part of another aspect.

It should be understood that the singular terms “a”, “an”, and “the” include plural references unless context clearly indicates otherwise. Similarly, the word “or” is intended to include “and” unless the context clearly indicates otherwise.

It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Approximating language, as used herein throughout the specification and claims, may be applied to modify any quantitative representation that could permissibly vary without resulting in a change in the basic function to which it is related. Accordingly, a value modified by a term or terms, such as “about,” “substantially”, is not limited to the precise value specified but within tolerances that are acceptable for operation of the aspect for an application for which it is intended. In some instances, the approximating language may correspond to the precision of an instrument for measuring the value.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The terms “first”, “second”, “third” detailed herein are used to distinguish one element from another similar element and may not necessarily denote order or relative importance, unless otherwise stated. For example, a first transaction data, a second transaction data may be used to distinguish two transactions based on two different foreign currency exchange.

The term “computing device” may be used herein to mean any suitable device and/or system such as, by way of example and not as a limitation, a personal computer, a laptop, a game console, a mobile phone and the like.

As used herein, the term “connect/connected/connection” may refer to a wired or wireless communication link formed between electronic devices that enables data transmission.

The term “processor” as used herein may be understood as any kind of entity that allows handling data. The data may be handled according to one or more specific functions executed by the processor or embedded controller. Further, a processor or embedded controller as used herein may be understood as any kind of circuit, e.g., any kind of analog or digital circuit. A processor or an embedded controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, embedded controller, or logic circuit. It is understood that any two (or more) of the processors, embedded controllers, or logic circuits detailed herein may be realized as a single entity with equivalent functionality or the like, and conversely that any single processor, embedded controller, or logic circuit detailed herein may be realized as two (or more) separate entities with equivalent functionality or the like.

The term “memory” detailed herein may be understood to include any suitable type of memory or memory device, e.g., a hard disk drive (HDD), a solid-state drive (SSD), a flash memory, etc.

As mentioned above, three-dimensional (3D) designs, also known as vertical integration, have become an effective alternative to traditional 2D chip designs for enhancing processing capabilities. These 3D packaging structures enhance the number of functions per unit area while maintaining or even reducing energy usage, all within the same or a reduced footprint. Consequently, electronic devices can be packaged more compactly. As the need for high performance computing grows, so does the number of layers in 3D packaging. For example, the bandwidth and storage capacity demand for computer memory (e.g., high bandwidth memory is anticipated to grow by two to threefold with each new generation. However, the integration of multiple tiers of memory dies stacked vertically introduces significant technical challenges and cost implications. The incorporation of through-silicon vias into each memory die for data transmission desires including the TSV fabrication process into the processing of active dies, such as those used for logic or memory; the additional processing can lead to reduced production yields, increased die size and increased manufacturing costs. Additionally, the space desired for TSVs on every die can limit circuit design options, amplify production costs and potentially impair device performance. These challenges pose limitations on the scalability of stacked memory technologies, impacting their feasibility for expanding to accommodate more tiers in future designs.

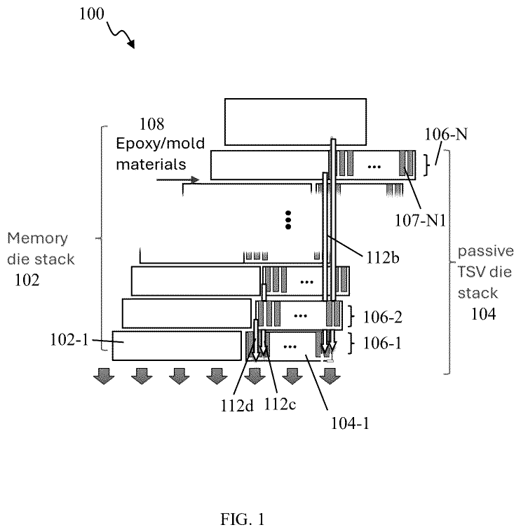

A solution to these challenges includes using an active die without TSVs alongside a separate passive die that contains TSVs for data transfer. FIG. 1 shows a schematic diagram illustrating a cross-sectional view of a 3D packaging structure 100 including active dies 102 without TSVs and separate passive dies 104 that contain TSVs (e.g., TSV 107-N1). An active die (e.g., a first active die 102-1) and a passive die (e.g., a first passive die 104-1) are assembled side-by-side laterally to create a single layer or tier (e.g., a first tier 106-1) while multiple such tiers 106-1, 106-2, . . . , 106-N are stacked vertically in N tiers and terraced (i.e., partially overlaps or laterally offset from each other) to form the 3D packaging structure 100. Epoxy/mold materials 108 are filled between the active dies 102 to provide mechanical support. The TSVs of the passive dies 104 are vertically aligned and connected across the multiple tiers 106 such that each of the active dies of a tier (e.g., tiers 106-2, . . . , 106-N) higher than the lowest tier (e.g., first tier 106-1) is connected to the lowest tier (e.g., a redistribution layer of the lowest tier) through the respective plurality of TSVs of a lower tier(s), illustrated by arrows (e.g., arrow 112b, 112c, 112d). This may mitigate the issues associated with TSV integration in active dies while benefiting from the advantages of 3D packaging.

However, as the need for high performance computing grows, so does the number of layers in 3D packaging. For example, the bandwidth and storage capacity demand for memory is anticipated to grow by two to threefold with each new generation. Due to these escalating requirements, the number of memory layers is expected to reach a high of 12 or even extend up to 16 layers (or tiers). However, there are other challenges in creating reliable and stable stacked terraced structures as more tiers are stacked. In particular, given the current technologies for die thinning and bumping processes, the stack up of the TSV dies and memory dies can have height variations that cause coplanarity issues. Such height variations and co-planarity issues can accumulate as more tiers are stacked, and also increase the possibility of poor bonding, die cracking, open joints and bridge joints. Additionally, the material such as epoxy/mold material 108 filled between the dies 102 in a stacked structure 100 is not designed for dissipating heat thus affecting the thermal performance of the stacked memory especially when more tiers are stacked.

Therefore, there is a need for an improved heat dissipation for dies of a stacked memory structure and a method for fabricating the same to address the issues, more particularly, to facilitate heat dissipation and enhance thermal envelope for stacked memory dies coupled to TSVs dies to build a high bandwidth memory.

Various non-limiting aspects described herein seek to provide an advantageous and scalable semiconductor device (e.g., memory unit, logic chip) with big solder bumps and additional metallization layers to increase the heat dissipation and enhance thermal envelope of the semiconductor device. The semiconductor device (e.g., memory unit, logic chip) may include a plurality of core dies and a plurality of passive dies arranged vertically in a plurality of tiers, each of the plurality of tiers comprising a respective core die arranged side-by-side laterally with a respective passive die, the plurality of core dies laterally offset from each other. Each of the plurality of passive dies includes a respective plurality of through-silicon vias (TSVs) and the respective pluralities of TSVs of the plurality of passive dies are vertically aligned. Additionally, each of the plurality of core dies further includes respective top and bottom metallization layers deposited on a top surface and a bottom surface of each of the plurality of core dies, respectively.

According to various non-limiting aspects described herein, a semiconductor device may include a first passive die and a first core die arranged side-by-side laterally in a first tier, wherein the first passive die comprises a plurality of through-silicon vias (TSVs) and the first core die comprises a first top metallization layer deposited on a top of the first core die and a first bottom metallization layer deposited on a bottom of the first core die; a second core die arranged in a second tier vertically on the first tier, wherein the second core die comprises a second top metallization layer deposited on a top of the second core die and a second bottom metallization layer deposited on a first portion of a bottom of the second core die; one or more first bumps disposed between a second portion of the bottom of the second core die and a top of the passive die, the one or more first bumps configured to couple (e.g., connect) the second core die to one or more TSVs of the plurality of TSVs of the first passive die; and a solder layer formed between the second bottom metallization layer and the first top metallization layer. The first bumps form core-die-to-passive-die and passive-die-to-passive-die connections or couplings between the first tier and the second tier and provide both physical and electrical connections or couplings between the first and second tiers, while the solder layer filled between the bottom metallization layer of the second core die and the top metallization layer of the first core die provides physical attachment or coupling that facilitates thermal dissipation and performance of the core dies of the first and second tiers. Stated differently, where a second tier of the plurality of tiers is stacked vertically on a first tier of the plurality of tiers, the semiconductor device further includes, a plurality of first bumps disposed between the first tier and the second tier, coupling (e.g., connecting) the plurality of TSVs of the respective passive die of the second tier and the respective core die of the second tier (e.g., on a second portion such as an overhang portion of the bottom of the respective core die of the second tier) to the respective plurality of TSVs of the respective passive die of the first tier, and a solder layer disposed between the respective bottom metallization layer of the respective core die of the second tier (e.g., disposed on a bottom of the respective core die of the second tier at a first portion such as a non-overhang portion) and the respective top metallization layer of the respective core die of the first tier. The plurality of first bumps form core-die-to-passive-die and passive-die-to-passive-die connections or couplings between the first tier and the second tier and provide both physical and electrical connections or couplings between the first and second tiers, while the solder layer filled between the respective bottom metallization layer of the respective core die of the second tier and the respective top metallization layer of the respective core die of the first tier provides physical attachment or coupling that facilitates thermal dissipation and performance of the respective core dies of the first and second tiers. In a non-limiting aspect, such solder layer includes a plurality of second bumps or a continuous layer formed by merging the plurality of second bumps.

Similarly, a third tier may be stacked vertically on the second tier of the plurality of tiers, and the semiconductor device may further include, a plurality of third bumps (or another plurality of first bumps) disposed between the second tier and the third tier, coupling (e.g., connecting) the plurality of TSVs of the respective passive die of the third tier and the respective core die of the third tier (e.g., a second portion such as an overhang portion of the bottom of the respective core die of the second tier) to the respective plurality of TSVs of the respective passive die of the second tier, and another solder layer disposed between the respective bottom metallization layer of the respective core die of the third tier (e.g., disposed on a first portion such as a non-overhang portion of the bottom of the respective core die of the third tier) and the top respective top metallization layer of the respective core die of the second tier. The plurality of second bumps form core-die-to-passive-die and passive-die-to-passive-die connections or couplings between the second tier and the third tier and provide both physical and electrical connections or couplings between the second and third tiers, while the another solder layer filled between the respective bottom metallization layer of the respective core die of the third tier and the respective top metallization layer of the respective core die of the second tier provides physical attachment or coupling that facilitates thermal dissipation and performance of the respective core dies of the second and third tiers. In a non-limiting aspect, such solder layer includes a plurality of fourth bumps (or another plurality of second bumps) or a continuous layer formed by merging the plurality of fourth bumps.

Stated differently, for every two tiers stacked vertically on one another among the plurality of tiers, the semiconductor device includes a respective plurality of first bumps disposed between a higher tier and a lower tier of the every two tiers, bonding and connecting the respective plurality of TSVs of the respective passive die of the higher tier and the respective bottom thermal conductive layer of the respective core die of the higher tier (e.g., disposed on a first portion such as a non-overhang portion of the bottom of the respective core die of the higher tier) to the respective plurality of TSVs of the respective passive die of the lower tier, forming core-die-to-passive-die and passive-die-to-passive-die connections between every two tiers. Such core-die-to-passive-die and passive-die-to-passive-die connections provide both physical and electrical connections across the tiers. A respective solder layer may be disposed between the respective bottom thermal conductive layer of the respective core die of the higher tier and the respective top metallization layer of the respective core die of the lower tier. Such solder layers filled between the plurality of core dies provide physical attachments or couplings that facilitate thermal dissipation and performance of the core dies. In one aspect described herein, such solder layer between every two tiers of the plurality of tiers may include a plurality of second bumps having at least one of (i) a wider pitch, (ii) a larger diameter, (iii) a greater protrusion height or (iv) a higher solder volume than the plurality of bumps between the two tiers. Such solder layer may be a continuous layer formed by merging the plurality of second bumps. Additionally, each of the top and bottom metallization layers may be made of a metal layer or a composite material, for example, an organic filler mixed with a metallic or ceramic material. Such semiconductor device design with bigger solder bumps and metallization layers offers low cost solutions to enhance high bandwidth memory thermal performance.

As used herein, the term “semiconductor device” may refer to a component such as a memory unit or a logic chip unit or a combination of both in computing systems, responsible for storing and processing digital data, respectively. In the context of a memory unit, it may play a pivotal role in facilitating rapid access to information during computing tasks, bridging the gap between processing units and long-term storage devices. Memory units may encompass both volatile types, such as RAM, which offer fast access speeds but desire continuous power to maintain data, and non-volatile types like read-only memory (ROM) and flash memory, which retain data even without power. The memory unit may include a high bandwidth memory unit in advanced computing systems. In the context of a logic chip unit, it may be responsible for executing instructions, performing logical operations and data manipulation within the systems. These units typically serve as the core processing such as central processing units (CPUs), graphics processing units (GPUs), or application-specific integrated circuits (ASICs). A semiconductor device may include multiple logic chips and memory units working in tandem to process and execute complex algorithms efficiently.

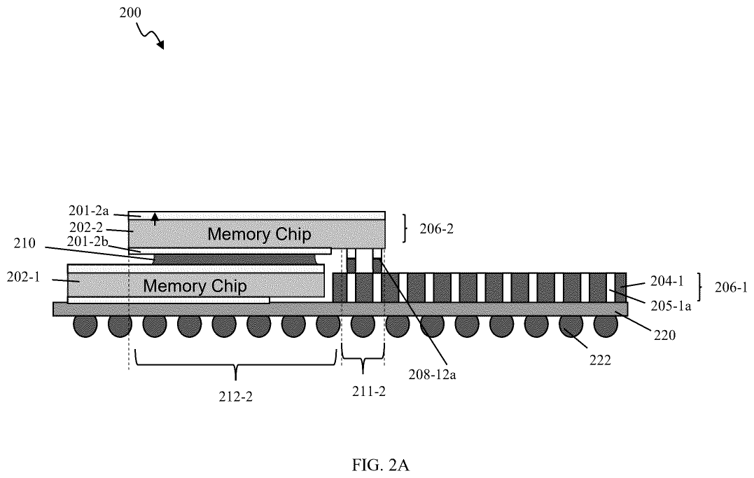

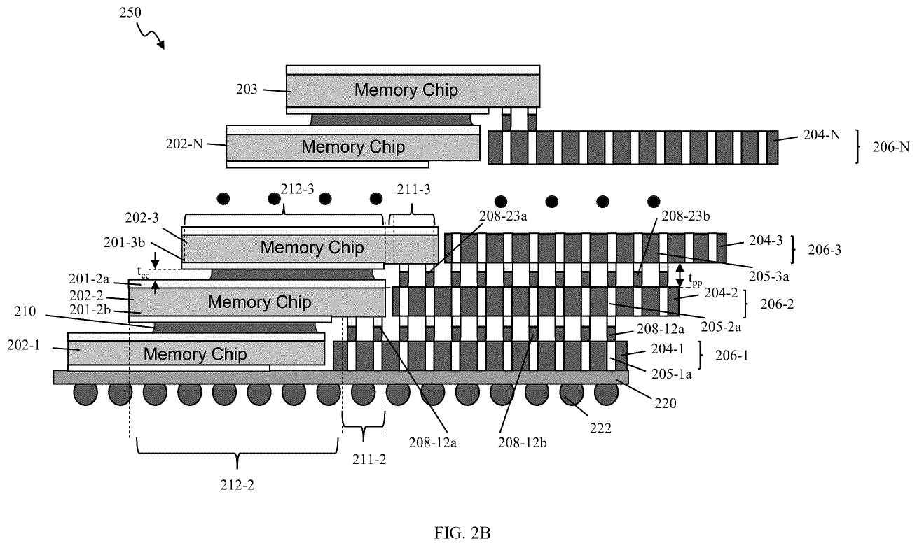

FIG. 2A shows a schematic diagram illustrating a non-limiting semiconductor device 200 according to various aspects described herein. The semiconductor device 200 may include a first passive die 204-1 and a first core die 202-1 (e.g., memory chip) arranged side-by-side laterally in a first tier 206-1 and a second core die 202-2 arranged in a second tier 206-2 vertically on the first tier 206-1. The first passive die includes a plurality of through-silicon vias (TSVs) (e.g., TSV 205-1a). Each of the first core die 202-1 and the second core die 202-2 include a top metallization layer (e.g., top metallization layer 201-2a) on a top of the core die and a bottom metallization layer (e.g., bottom metallization layer 201-2b) on a bottom of the core die. In particular, the bottom metallization layer is disposed on a first portion (e.g., portion 212-2 of the second core die 202-2) of the bottom of the core die. The semiconductor device 200 may further include one or more first bumps (e.g., bump 208-12a) between a second portion (e.g., portion 211-2 of the second core die 202-2) of the bottom of the second core die 202-2 and a top of the first passive die. In this example, the second core die 202-2 is laterally offset from the first core die 202-1, forming the second portion 211-2 or an overhang portion. In particular, the second core die 202-2 is electrically coupled (e.g., connected) to one or more TSVs of the plurality of TSVs through the one or more first bumps. The semiconductor device 200 may further include a solder layer 210 formed between the bottom metallization layer 201-2b of the second core die 202-2 and the top metallization layer of the first core die 202-1, configured to physically couple (e.g., attach) the two metallization layers of the two core dies across two tiers.

The semiconductor device 200 may contain more than two tiers. FIG. 2B shows a schematic diagram illustrating a non-limiting semiconductor device 250 according to various aspects described herein. For purpose of brevity and to avoid unnecessary repetition, components that perform the same or equivalent functions across FIGS. 2A and 2B are designated using the same reference numerals. The description of components bearing the same reference numerals, as detailed in connection with FIG. 2A, may be omitted or may not be repeated in detail in connection with FIG. 2B. However, where applicable, additional details, specific differences, or unique aspects relevant to particular components in FIG. 2B will be described and highlighted as follows. The semiconductor device 250 may contain more than two tiers, that is, in addition to the first passive die 204-1, the first core die 202-1 and the second core die 202-2, the semiconductor device 250 may further include a second passive die 204-2 arranged side-by-side laterally with the second core die 202-2 in the second tier 206-2. The second passive die also includes a plurality of second through-silicon vias (TSVs) (e.g., second TSV 205-2a). The semiconductor device 250 may further contain a third core die 202-3 arranged vertically on the second core die 202-2 in a third tier 206-3. The third core die 202-3 also includes a top metallization layer on a top of the core die and a bottom metallization layer on a bottom of the third core die 202-3. In particular, the bottom metallization layer is disposed on a first portion 212-3 of the third core die 202-3. The semiconductor device 250 may further include one or more third bumps (e.g., third bump 208-23a) between a second portion 211-3 of the bottom of the second core die 202-2 and a top of the second passive die. In this example, the third core die 202-3 is laterally offset from the second core die 202-2, forming the second portion 211-3 or an overhang portion. Similarly, the third core die 202-3 is electrically coupled (e.g., connected) to one or more second TSVs of the plurality of second TSVs through the one or more third bumps. The semiconductor device 250 may further include a second solder layer formed between the bottom metallization layer of the third core die 202-3 and the top metallization layer of the second core die 202-3, configured to physically couple (e.g., attach) the two metallization layers of the two core dies across the second and third tiers. Stated differently, the semiconductor device 250 includes a plurality of core dies (e.g., memory chips) such as core dies 202-1, 202-2, 202-3, 202-N without TSVs and a plurality of separate passive dies such as passive dies 204-1, 204-2, 204-3, 204-N each containing a respective plurality of TSVs (e.g., TSV 205-1a of passive die 204-1). A core die (e.g., core die 202-1) and a passive die (e.g., passive die 204-1) are disposed side-by-side laterally to create a single layer or tier (e.g., a first tier 206-1) while multiple such tiers 206-1, 206-2, . . . , 206-N are stacked vertically in a plurality of tiers (N number of tiers, 1^{st} to Nth tier). Each core die of a higher tier (e.g., second to Nth tiers 206-2, 206-3, 206-N) higher than a lowest tier (e.g., first tier 206-1) is laterally offset from the respective core die of a lower tier (e.g., second tier 206-2 in case third tier 206-3 is the higher tier) and partially overlaps the respective passive die of the lower tier, thereby forming a terraced memory structure 250 on a redistribution layer 220. Each core die (e.g., core die 201-2) further includes a respective top metallization layer (e.g., top metallization layer 201-2a) and a respective bottom metallization layer (e.g., bottom metallization layer 201-2b) at a top surface and a bottom surface, respectively. Additionally, the respective pluralities of TSVs of the plurality of passive dies 204 are vertically aligned. The semiconductor device 250 may also include a controller die or another core die 203 (e.g., memory chip) stacked on the core die of a highest tier (e.g., core die 202-N of Nth tier 206-N).

According to various aspects, as the second (higher) tier 206-2 is stacked vertically on the first (lower) tier 206-1, there are (i) a plurality of bumps including bumps 208-12a, 208-12b disposed between the second tier 206-2 and the first tier 206-1 coupling (e.g., connecting) the plurality of TSVs (e.g., TSV 205-2a) of the passive die 204-2 of the second tier 206-2 and the core die 202-2 of the second tier 206-2 (e.g., at a second portion 211-2 (overhang-portion) of a bottom of the core die 202-2) to the plurality of TSVs (e.g., TSV 205-1a) of the passive die 204-1 of the first tier 206-1, and (ii) a solder layer 210 disposed between the second tier 206-2 and the first tier 206-1, more particularly, between the bottom metallization layer 201-2b of the core die 202-2 of the second tier 206-2 disposed on a first portion 212-2 (e.g., non-overhang portion of the core die 202-2) of a bottom of the core die 202-2 and the top metallization layer of the core die 201-1 of the first tier 206-1. Similarly, as the third (higher) tier 206-3 is stacked vertically on the second (lower) tier 206-2, there are also (i) another plurality of bumps including bumps 208-23a, 208-23b disposed between the third tier 206-3 and the second tier 206-2 coupling (e.g., connecting) the plurality of TSVs (e.g., TSV 205-3a) of the passive die 204-3 of the third tier and the core die 202-3 of the third tier 206-3 (e.g., on a second portion 211-3 (overhang portion) of a bottom of the core die 202-3) to the plurality of TSVs (e.g., TSV 205-2a) of the passive die 204-2 of the second tier 206-2, and (ii) another solder layer disposed between the third tier 206-3 and the second tier 206-2, more particularly, between the bottom metallization layer 201-3b of the core die 202-3 of the third tier 206-2 disposed on a first portion 212-3 (non-overhang portion of the core die 202-3) of a bottom of the core die 202-3 and the top metallization layer of the core die 201-2 of the second tier 206-2.

In fact, for every two tiers (e.g., first tier 206-1 with second tier 206-2, second tier 206-2 with third tier 206-3, Nth tier 206-N with (N−1)th tier 206-(N−1)) stacked vertically on one another among the plurality of tiers 206, the semiconductor device 250 further includes a respective plurality of bumps coupling (e.g., connecting) the respective plurality of TSVs of the respective passive die and the respective core die of a higher tier between the every two tiers to the respective plurality of TSVs of the respective passive die of a lower tier between the every two tiers; and a solder layer between the respective bottom thermal conductive layer of the respective core die of the higher tier and the respective top thermal conductive layer of the respective core die of the lower tier.

The plurality of bumps (e.g., bump 208) and TSVs are aligned and coupled during the assembly of the terraced semiconductor device 250. This provides both physical and electrical connections or couplings among the passive dies and among the core dies and passive dies, where the bumps at the second portions of the core dies couple (e, g., connect) with the TSVs of the passive dies and form joints with the passive dies. As such, the core dies of all higher tiers (e.g., second to Nth tiers 206-2, 206-3, 206-N) higher than the lowest tier (e.g., first tier 206-1) among the plurality of tiers 206 are coupled (e.g., connected) to the redistribution layer 220 through respective vertically aligned and coupled bumps and TSVs of their respective lower tiers across the plurality of tiers 206; whereas the core die (e.g., core die 202-1) of the lowest tier (e.g., first tier 206-1) may be coupled (e.g., connected) to the redistribution layer 220 through its bottom metallization payer and/or conductive pads/wires. Additionally, the redistribution layer 220 may further include a plurality of bottom bumps (e.g., bump 222) configured to couple (e.g., connect) to a substrate or interposer such that, when the plurality of bottom bumps are coupled (e.g., attached) to a substrate or interposer, the plurality of core dies 202 which are coupled (e.g., connected) to the redistribution layer 220 are in turn coupled (e.g., connected) to the substrate or interposer.

The respective solder layers (e.g., solder layer 210) may be formed during the stacking of respective core dies to form a plurality of tiers during the assembly of the terraced semiconductor device 250. The formation of a solder layer between two tiers stacked vertically on one another may be through coupling (e.g., attaching) a respective plurality of solder bumps between the core dies of two tiers, for example, those solder bumps protruding downwards from the respective first portion of the respective core die of a higher tier between the two tiers to the respective core die of a lower tier. The formation of such solder layer may include further squeezing the respective plurality of solder bumps between the core dies of the two tiers, deforming the respective plurality of solder bumps to spread them laterally to fill the air gaps between the solder bumps and eventually merge the respective plurality of second bumps to form the solder layer.

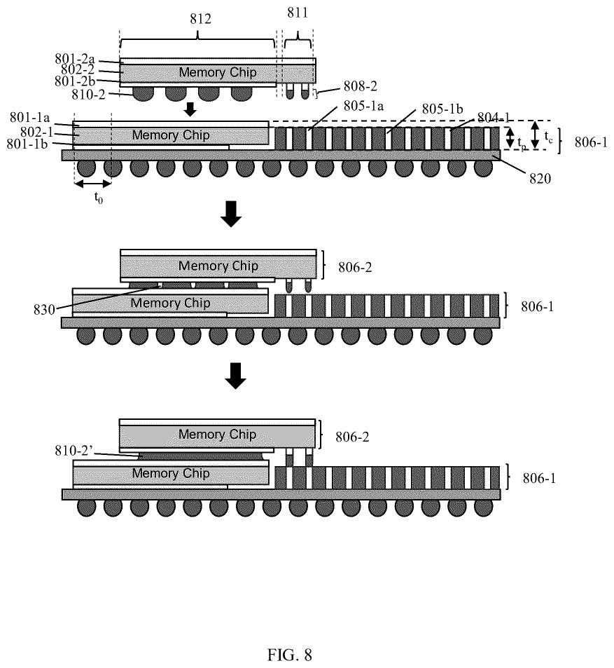

The solder layers once formed provides physical connections or coupling and facilitates thermal dissipation between the core dies. The solder layers (e.g., solder layer 210) may contain blocks or grains resembling the plurality of solder bumps. To enhance its thermal dissipation and performance, the squeezing step may be carried out appropriately, for example, with adequate time, pressure and/or temperature such that the solder bumps are spread laterally to fill and eliminate air gaps between the solder bumps and merged into a continuous solder layer. More details will be shown in FIG. 8 and elaborated in its accompanying description below. With the metallization layers and merged solder layers coupling (e.g., connecting) the plurality of core dies 202, the memory die stack in the semiconductor device 250 may have better heat dissipation. In a non-limiting aspect, for each tier of the plurality of tier, the each core die has a greater thickness (t_{c}) (i.e., thicker) than that (tₚ) of the passive die in each tier, and results in smaller gap between the core dies, denoted as t_{cc}, as compared to that between the passive dies, denoted as t_{cc}, i.e. t_{cc}<tₚₚ. This will enhance thermal performance due to the shorter thermal path between the core dies.

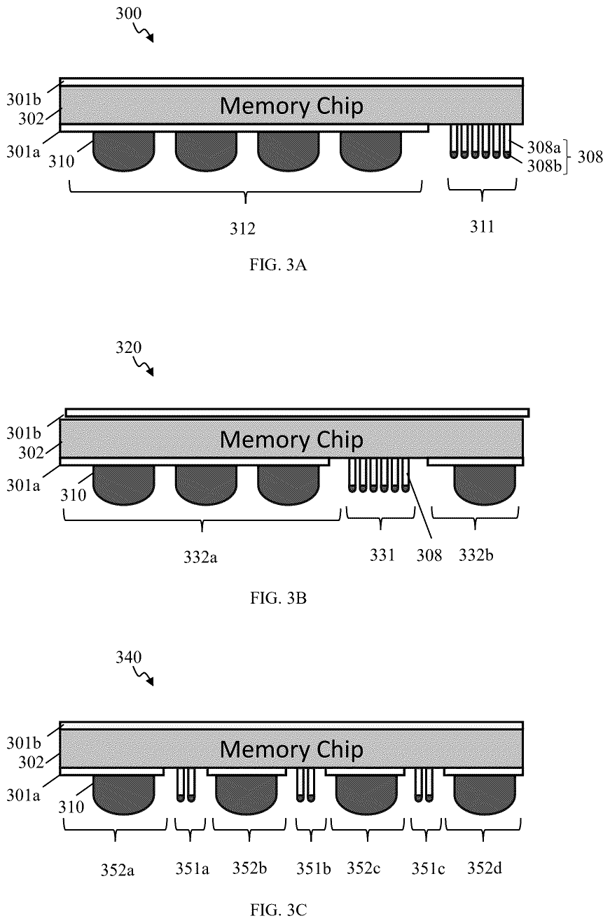

FIG. 3A shows a schematic diagram illustrating a non-limiting core die 300 (e.g., memory chip) according to various aspects described herein. The core die 300 may include a top metallization layer 301b at a top of the core die 300 and a bottom metallization layer 301a disposed on a first portion 312 of a bottom of the core die 300. The core die 300 may further include a plurality of first bumps (e.g., first bump 308) disposed on a second portion 311 of a bottom of the core die 300 and a plurality of second bumps (e.g., second bump 310) on the bottom metallization layer 301a protruding downwards away from the top metallization layer 301b. The metallization layers 301a, 301b may be simple metal layers made of gold or composite materials, for example, synthesized composite materials that contain a metallic or ceramic material mixed with organic fillers, and may be respectively deposited on the top and bottom surfaces of the core die 300 using a deposition process such as a chemical vapor deposition (CVD) process or a plasma enhanced (PE) CVD process. FIGS. 3B and 3C show schematic diagrams illustrating other non-limiting core dies 320, 340 according to various aspects described herein. For purpose of brevity and to avoid unnecessary repetition, components that perform the same or equivalent functions across FIGS. 3A, 3B and 3C are designated using the same reference numerals. The description of components bearing the same reference numerals, as detailed in connection with FIG. 3A, may be omitted or may not be repeated in detail in connection with FIGS. 3B and 3C. However, where applicable, additional details, specific differences, or unique aspects relevant to particular components in FIGS. 3B and 3C will be described and highlighted as follows. In particular, the first portion of the core die on which the bottom metallization layers and the second bumps are disposed for forming solder layers and core-die-to-core-die connections or couplings and the second portion of the core die on which the first bumps are disposed for core-die-to-passive-die connections or couplings may not be at both distinct ends of the core dies. For example, referring to FIG. 3B, the core die 320 may contain two first portions 332a, 332b on both left and right ends of the core die 320 while the second portion 331 is at a relative central region of the core die 320. Consequently, the second bumps extend out at the first portions 332a, 332b of the core die and the first bumps extend out at the second portions 331 of the core die 320. In particular, from left end to right end, the core die 320 may contain three second bumps for coupling (e.g., attaching) to a core die of a lower tier, followed by first bumps for coupling (e.g., connecting) to the passive die of the lower tier and another one second bump for coupling (e.g., attaching) to a core die of the lower tier. Referring to FIG. 3C, the core die 340 may contain alternative first portions 352a, 352b, 352c, 352d, and second portions 351a, 351b, 351c. Consequently, from left end to right end, one second bump and two first bumps are alternatingly extending out of the core die 340.

In various aspects described herein, the plurality of first bumps and the plurality of second bumps are two different types of bump. The plurality of first bumps are of a first type of bump and the plurality of second bumps are of a second type of bump. In particular, each first bump of the plurality of first bumps may be a metal/solder bump which has a pillar (e.g., pillar 308a) disposed on the bottom metallization layer 310a protruding downwards away from the top metallization layer 301b and a solder tip (e.g., solder tip 308b) disposed on and extending away from the pillar. Each second bump of the plurality of second bumps may be a pure solder bump made of a solder material. The second bump may have a bigger/wider pitch (i.e., bump to bump spacing), a larger diameter, a greater protrusion height and/or a higher solder volume as compared to the first bump which may have a denser/narrower pitch, a smaller diameter and/or less solder volume. The pillar is typically made of a metal such as copper (Cu) while the solder tip and the solder bump are made of a different solder material is typically an alloy of tin (Sn), silver (Ag) and copper (Cu). The Cu pillar may be formed using an electroplating process and the solder tip and solder bump may be respectively disposed using a solder printing process. In a non-limiting aspect, both of the pillar and the solder tip are made of the same material, for example, a single metal or a single alloy.

The core die 300 may refer to one of the plurality of core dies 202 of a higher tier (e.g., second to Nth tier 206-2, 206-3, . . . , 206-N) among the plurality of tiers 206 shown in FIG. 2B prior to stacking vertically onto another core die and assembling into the semiconductor device 250, and during the assembly of a semiconductor device (e.g., semiconductor device 250), the plurality of first bumps (e.g., the respective solder tips of the plurality of first bumps) may be configured to couple (e.g., connect) to respective TSVs of the passive die of the lower tier overlapped by the core die 300 to provide physical and electrical connections or couplings across the tiers; whereas the plurality of second bumps may be coupled (e.g., attached) to the core die of the lower tier overlapped by the core die 300 to provide physical connections or couplings between the core dies. During the assembly of semiconductor device (e.g., semiconductor device 250), as the core die 300 is stacked vertically on a core die of a lower tier and the plurality of first bumps is bonded or coupled or connected to TSVs of a passive die to form core-die-and-passive-die joints between the two tiers, the plurality of second bumps may be squeezed, deformed, spread laterally and eventually merged into a solder layer between the core die 300 and the core die of the lower tier.

Various non-limiting aspects described herein seek to provide a method for fabricating the above-described semiconductor device (e.g., memory unit, logic chip) with big solder bumps and additional metallization layers to increase the heat dissipation and enhance thermal envelope of the semiconductor device. The method may broadly include depositing a first top metallization layer on a top of a first core die; and depositing a first bottom metallization layer on a bottom of the first core die; depositing a second top metallization layer on a top of the second core die; depositing a second bottom metallization layer on a first portion of a bottom of the second core die; disposing one or more first bumps on a second portion of the bottom of the second core die; and coupling the second core die to one or more TSVs of a plurality of TSVs of the first passive die through the one or more first bumps. In some embodiments, the method may further include disposing a plurality of second bumps on the second bottom metallization layer; and coupling the second bottom metallization layer to the first top metallization layer through the plurality of second bumps to form a solder layer between the second bottom metallization layer and the first top metallization layer. Additionally, the coupling the second bottom metallization layer to the first top metallization layer through the plurality of second bumps to form the solder layer between the second bottom metallization layer and the first top metallization includes merging the plurality of second bumps into the solder layer. In some embodiments, the method may further include disposing a plurality of the first bumps on a bottom of a second passive die; and coupling a plurality of second TSVs of the second passive die to the plurality of TSVs other than the one or more TSVs through the plurality of the first bumps. Additionally, the method may also further include depositing a third top metallization layer on a top of a third core die; depositing a third bottom metallization layer on a first portion of a bottom of the third core die; disposing one or more third bumps on a second portion of the bottom of the third core die and a plurality of the third bumps on the third passive die; disposing a plurality of fourth bumps on the third bottom metallization layer; and coupling the third core die to one or more second TSVs of the second passive die through the plurality of the third bumps. Additionally, the method may further include coupling the third bottom metallization layer to the second top metallization layer through the plurality of fourth bumps to form a second solder layer between the third bottom metallization layer and the second top metallization layer.

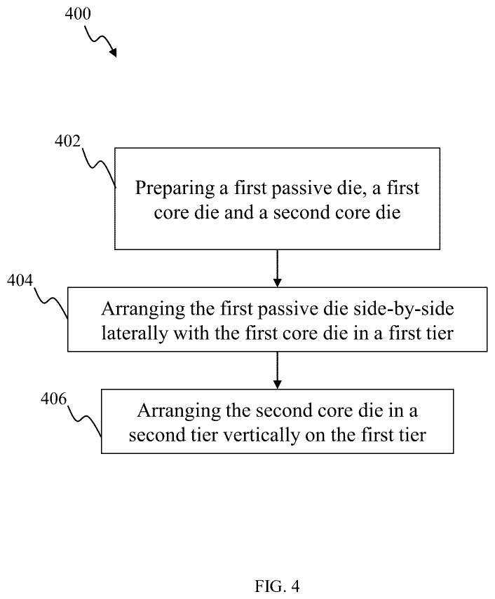

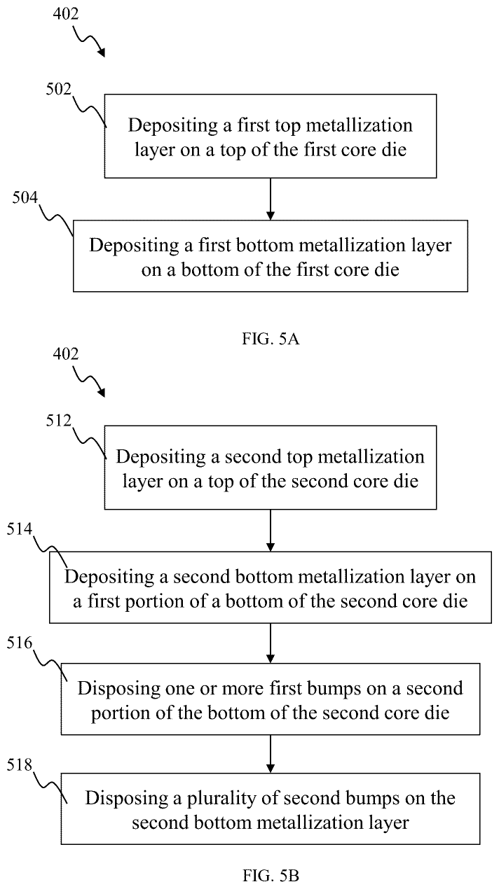

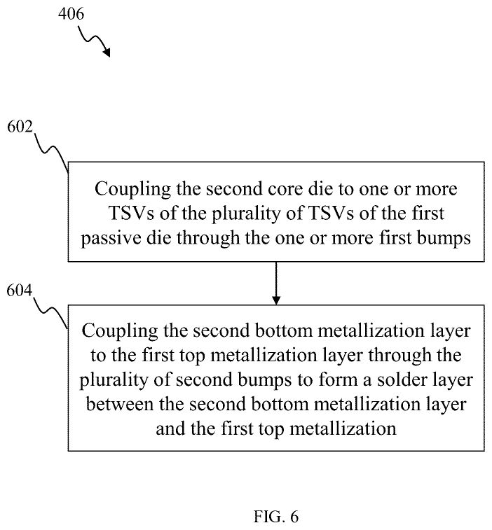

FIG. 4 shows a flow chart illustrating a method 400 for fabricating a semiconductor device (e.g., semiconductor device 250) according to various non-limiting aspects described herein. FIGS. 5A and 5B show flow charts illustrating processes of step 402 of the method 400 of FIG. 4 according to a non-limiting aspect described herein. FIG. 6 shows a flow chart illustrating step 404 of the method 400 of FIG. 4 according to a non-limiting aspect described herein.

The method 400 may include: in step 402, preparing a first passive die, a first core die and a second core die, in step 404, arranging the first passive die side-by-side laterally with the first core die in a first tier; and in step 406, arranging the second core die in a second tier vertically on the first tier. The method 400, when preparing the first core die in step 402, may further include: in step 502, depositing a first top metallization layer on a top of the first core die; and in step 504, depositing a first bottom metallization layer on a bottom of the first core die.

According to various aspects described herein, the method 400, when preparing the first core die in step 402, may further include: in step 502, depositing a first top metallization layer on a top of the first core die; and in step 504, depositing a first bottom metallization layer on a bottom of the first core die. The method 400, when preparing the second core die (e.g., core dies 300, 320, 340) in step 402, may further include: in step 512, depositing a second top metallization layer on a top of the second core die; in step 514, depositing a second bottom metallization layer on a first portion of a bottom of the second core die; and in step 516, disposing one or more first bumps on a second portion of the bottom of the second core die. In some embodiments, the method 400, when preparing the second core die in step 402, may further include: in step 518, disposing a plurality of second bumps on the second bottom metallization layer.

The method 400, when arranging the second core die in the second tier vertically on the first tier in step 406, may further include: in step 602: connecting the second core die to one or more TSVs of the plurality of TSVs of the first passive die through the one or more bumps. In some embodiments, after step 518 is carried out to dispose a plurality of second bumps on the second bottom metallization layer, the method 400, when arranging the second core die in the second tier vertically on the first tier in step 406 may further include: in step 604, attaching the second bottom metallization layer to the plurality of second bumps to form a solder layer between the second bottom metallization layer and the first top metallization. In various aspects described herein, the step of attaching the second bottom metallization layer to the plurality of second bumps to form a solder layer between the second bottom metallization layer and the first top metallization in step 604 may include merging (e.g., squeezing and deforming) the plurality of second bumps into the solder layer.

In other words, the method 400 may include: in step 402, preparing a plurality of core dies and a plurality of passive dies, where each of the plurality of passive dies includes a respective plurality of TSVs, and in step 404, arranging the plurality of core dies and the plurality of passive dies vertically in a plurality of tiers such that each of the plurality of tiers comprises a respective core die arranged side-by-side laterally with a respective passive die, the plurality of core dies are laterally offset from each other, and the respective pluralities of TSVs of the plurality of passive dies are vertically aligned.

The method 400, when preparing each of the plurality of core dies in step 402, may further include: depositing a respective top metallization layer on a top of the each of the plurality of core dies and a bottom metallization layer on a first portion of a bottom of the each of the plurality of core dies (e.g., first portions 312, 332a, 332b, 352a, 352b, 352c of a bottom of the core dies 300, 320, 340).

According to various aspects described herein, where preparing the respective core die (e.g., core die 300) and the respective passive die of a second tier (e.g., higher tier) of the plurality of tiers in step 402 may include a step of disposing a plurality of first bumps (e.g., first bump 308) on a bottom surface of the respective passive die of the second tier and on a second portion of a bottom of the respective core die (e.g., second portions 311, 331, 351a, 351b, 351c of the bottom of core dies 300, 320, 340) of the second tier, the plurality of first bumps protruding downwards from the respective passive die of the second tier and from the respective core die of the second tier at the second portion, the respective plurality of first bumps attached to the respective plurality of TSVs of the respective passive die of the second tier (e.g., higher tier); and a step of disposing a plurality of second bumps (e.g., second bump 310) on the respective bottom metallization layer of the respective core die of the second tier, the plurality of second bumps protruding downwards from the respective bottom metallization layer. Additionally, when arranging the respective core (e.g., core die 300) and the respective passive in the second tier vertically on the first tier of the plurality of tiers, step 404 may include a step of connecting the plurality of first bumps to the respective plurality of TSVs of the respective passive die of the first tier, forming core-die-to-passive-die and passive-die-to-passive-die connections between the first and second tiers to provide both physical and electrical connections between the first and second tiers, and a step of attaching the plurality of second bumps to the respective core die of the first tier to form a solder layer between the respective bottom metallization layer of the respective core die of the second tier and the respective top metallization layer of the respective core die of the first tier that provide physical attachments that facilitate thermal dissipation and performance of the respective core dies. The same steps for disposing a plurality of first bumps (or a plurality of third bumps) and a plurality of second bumps (or a plurality of fourth bumps), connecting the plurality of first bumps and attaching the plurality of second bumps may be carried out when preparing the respective core die and the respective passive die of the third tier and arranging the respective core die and the respective passive die of the third tier vertically on the second tier of the plurality of tiers.

Stated differently, when preparing the respective core die and the respective passive die of a higher tier between every two tiers stacked vertically on one another among the plurality of tiers during step 402, the method 400 may further include: in step 504, disposing a respective plurality of first bumps on a bottom surface of the respective passive die of the higher tier and on the respective core die of the higher tier (e.g., a second portion of a bottom of the respective core die of the higher tier), the respective plurality of first bumps attached to the respective plurality of TSVs of the respective passive die of the higher tier; and in step 506, disposing a respective plurality of second bumps on the respective bottom metallization layer of the respective core die of the higher tier, the plurality of second bumps protruding downwards away from the respective top metallization layer.

Additionally, when arranging the plurality of core dies and the plurality of passive dies vertically in a plurality of tiers in step 404, the method 400 may further include: in step 602, for arranging two tiers vertically on one another, coupling (e.g., connecting) the respective plurality of first bumps of the respective core die of a higher tier between the every two tiers to the respective plurality of TSVs of the respective passive die of a lower tier between the every two tiers; and in step 604, coupling (e.g., attaching) the respective plurality of second bumps of the higher tier to the respective top metallization layer of the respective core die of the lower tier to form a respective solder layer between the respective bottom metallization layer of the respective core die of the higher tier and the respective top metallization layer of the respective core die of the lower tier.

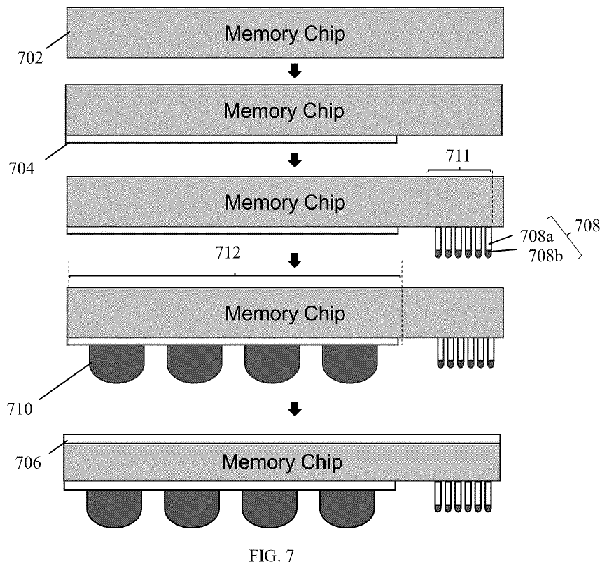

FIG. 7 shows a schematic diagram illustrating a process of preparing a core die (e. g core die 300) according to a non-limiting aspect described herein. The process may include steps 504 and 506 of the method 500 and step 402 of the method 400 shown in FIGS. 4 and 5 for preparing a core die of a higher tier between two tiers stacked vertically on one another and may start by depositing a bottom metallization layer 704 on a wafer, for example, using a CVD or PECVD process. The bottom metallization layer 701-2b may be a simple metal layer made of gold or made of a composite material, for example, a synthesized composite material that contains a metallic or ceramic material mixed with organic fillers. It is noted multiple core dies (e.g., memory chip) may be fabricated and prepared at different portions of the wafer 702. For sake of simplicity, only a portion of the wafer 702 forming a core die (e.g., core die 300) of a semiconductor device (e.g., semiconductor device 250) is shown in FIG. 7.

Subsequent to depositing the bottom metallization layer 704, steps 504 and 506 may be carried out, where a plurality of first bumps (e.g., first bump 708) may be formed on a respective second portion 711 of a bottom of the wafer 702 corresponding to a core die/memory chip, and a plurality of second bumps (e.g., second bump 710) may be formed on the bottom metallization layer 701-2b formed on a first portion 712 of the bottom of the wafer 702 corresponding to the core die/memory chip.

Each first bump of the plurality of first bumps may be formed by first electroplating a Cu pillar (e.g., pillar 708a) on the respective second portion 711 of the wafer 702 and then disposing a solder tip (e.g., solder tip 708b) on and extending away from the pillar 708a and away from the wafer 702 using a solder printing process. The solder tip 708b may be made of a solder material such as an Sn—Ag—Cu alloy. Each second bump of the plurality of second bumps on the bottom metallization layer 704 may be formed using a solder printing process. Each second bump may be a pure solder bump which is made of a solder material such as an Sn—Ag—Cu alloy. In a non-limiting aspect, both of the pillar and the solder tip are made of the same material, for example, a single metal or a single alloy. The second bump may also have a bigger/wider pitch (i.e., bump to bump spacing), a larger diameter, a greater protrusion height and/or a higher solder volume as compared to the first bump which may have a denser/narrower pitch, a smaller diameter and/or less solder volume. The bigger/wider pitch (i.e., bump to bump spacing), larger diameter, greater protrusion height and/or higher solder volume may be beneficial for subsequent squeezing and merging of the bumps to form a solder layer during the assembly of the semiconductor device.

Subsequent to forming the plurality of first and second bumps of the bottom metallization layer 704, a top metallization layer 706 may be deposited on a top surface opposite the bottom surface of the wafer 702, for example, using a CVD or PECVD process. The top metallization layer 706 may be a simple metal layer such as gold or made of a composite material, for example, a synthesized composite material that contains a metallic or ceramic material mixed with organic fillers. Optionally, prior to the deposition of the top metallization layer 706 of the top surface of the wafer 702, a step of grinding the top surface of the wafer 702 may be carried to reduce the thickness of the wafer 702 to a desired thickness and a step of dicing the wafer 702 is carried out to form a core die(s) (e.g., memory chip(s)). Such process may be used to prepare the core die of each higher tier to be stacked vertically onto another core die of a lower tier to form a semiconductor device (e.g., semiconductor device 250).

FIG. 8 shows a schematic diagram illustrating a process of fabricating a semiconductor device according to a non-limiting aspect described herein. The process may include steps 602 and 604 of the method 600 and step 404 of the method 400 shown in FIGS. 4 and 6 for stacking two tiers vertically on one another. In this aspect, there is a first tier 802-1 with a first core die 802-1 arranged side-by-side laterally with a passive die 804-1 containing a plurality of TSVs (e.g., TSV 805-1a) on a redistribution layer 820, and a second core die is to be arranged vertically on the first core die 802-1 of the first tier 806-1 to form a second tier 806-2 on the first tier 806-1. The first and second core dies may be prepared and fabricated through the processes illustrated in FIGS. 5A and 5B. The second core die 802-2 is laterally offset from the first core die 802-1 of the first tier 806-1 and overlaps the first passive die 804-1 of the first tier, the offset denoted as t₀. In one non-limiting aspect, the offset is configured such that the second portion 811 the second core die 802-2 forms an overhang portion of the second core die 802-2 overlapping the first passive die 804-1. In a non-limiting aspect, the first core die has a greater thickness, denoted as t_{c}, i.e., thicker, than that, denoted as tₚ, of the first passive die in the first tier (and so does other core dies and passive dies on other tiers). This results in a smaller gap between the core dies as compared to that between the passive dies. This will enhance thermal performance due to the shorter thermal path between the core dies.

The stacking of the second core die 802-2 on the first core die 802-1 of the first tier 806-1 to form the second tier 806-2 on the first tier 806-1 may be carried out by respectively connecting the plurality of first bumps (e.g., first bump 808-2) disposed on the second portion 811 of the second core die 802-2, protruding downwards away from the top metallization layer 801-2a, to the plurality of TSVs (e.g., TSV 805-1a) of the first passive die 804-1 of the first tier 806-1 overlapped by the second portion 811 of the second core die 802-2 and attaching the plurality of second bumps (e.g., second bump 810-2) disposed on the bottom metallization layer 801-2b disposed on the first portion 812 (non-overhang portion or a portion other than the overhang portion 811 of) of the second core die 802-2, protruding downwards away from the top metallization layer 801-2a, to the top metallization layer 801-1a of the first core die 802-1.

In this aspect, the second bump has a wider pitch, a larger diameter, a greater protrusion height and a higher solder volume and due to this, when attaching the plurality of second bumps to the top metallization layer 801-1a of the first core die 802-1 and connecting the plurality of first bumps to the TSVs of the first passive die 804-1 to form joints with the first passive die 804-1, the plurality of second bumps may be squeezed, deformed and spread laterally to fill the air gaps (e.g., air gap 830) between the second bumps to form a solder layer. Such solder layer provides physical connections and facilitates the thermal dissipation between the core dies 802-1 and 802-2. In one non-limiting aspect, adequate time, pressure and temperature may be applied to ensure the air gaps between the second bumps are eliminated and such that the plurality of second bumps are merged into a continuous solder layer 810-2′ with better thermal dissipation and performance. Subsequently, a second passive die having a plurality of TSVs may be arranged side-by-side laterally with the second core die 802-1, where the plurality of TSVs and a plurality of bumps of the second passive die are aligned with and connected to respective TSVs (e.g., TSV 805-1b) of the first passive die 806-1 to complete the formation of the second tier 806-2. This process of stacking of a core die (e.g., core die 300, 802-2) to form a new tier may be repeated until the desired number of tiers in a stacked semiconductor device (e.g., semiconductor device 250) are formed.

The following examples pertain to various aspects of the present embodiment. [To be updated when claims are finalized]

Example 1 is a semiconductor device comprising: a first passive die and a first core die arranged side-by-side laterally in a first tier, wherein the first passive die includes a plurality of through-silicon vias (TSVs) and the first core die includes a first top metallization layer deposited on a top of the first core die and a first bottom metallization layer deposited on a bottom of the first core die; a second core die arranged in a second tier vertically on the first tier, wherein the second core die includes a second top metallization layer deposited on a top of the second core die and a second bottom metallization layer deposited on a first portion of a bottom of the second core die; and one or more first bumps disposed between a second portion of the bottom of the second core die and a top of the first passive die, the one or more first bumps configured to couple the second core die to one or more TSVs of the plurality of TSVs of the first passive die.

In Example 2, the subject matter of Example 1 may optionally include a solder layer formed between the second bottom metallization layer and the first top metallization layer.

In Example 3, The subject matter of Example 1 may optionally include that the solder layer includes a plurality of second bumps configured to couple the second bottom metallization layer to the first top metallization layer.

In Example 4, the subject matter of Example 3 may optionally include that the plurality of second bumps have at least one of (i) a wider pitch, (ii) a larger diameter, (iii) a greater protrusion height or (iv) a higher solder volume than the respective plurality of first bumps.

In Example 5, the subject matter of Example 3 or 4 may optionally include that each of the plurality of second bumps includes a pillar and a solder tip, the pillar disposed on the second bottom metallization layer and the solder tip extending away from the pillar.

In Example 6, the subject matter of Example 5 may optionally include that the pillar and the solder tip are made of one of (i) a single metal or (ii) a single alloy.

In Example 7, the subject matter of any one of Example 1-6 may optionally include: a second passive die arranged side-by side laterally with the second core die in the second tier, wherein the second passive die includes a plurality of second TSVs; and a plurality of first bumps disposed between a bottom of the second passive die and the top of the first passive die, the plurality of first bumps configured to couple the plurality of second TSVs to the plurality of TSVs of the first passive die other than the one or more TSVs.

In Example 8, the subject matter of Example 7 may optionally include: a third core die arranged in a third tier vertically on the second tier, wherein the third core die includes a third top metallization layer deposited on a top of the third core die and a third bottom metallization layer deposited on a first portion of a bottom of the third core die; and one or more third bumps disposed on a second portion of the bottom of the third core die, the one or more third bumps configured to connect the third core die to one or more second TSVs of the plurality of second TSVs of the second passive die.

In Example 9, the subject matter of Example 8 may optionally include a second solder layer formed between the third bottom metallization layer and the second top metallization layer.

In Example 10, the subject matter of any one of Examples 1-9 may optionally include that one or more metallization layers among the first top metallization layer, the first bottom metallization layer, the second top metallization layer or the second bottom metallization layer are made of one of (i) metals or (ii) composite materials.

In Example 11, the subject matter of any one of Examples 1-10 may optionally include that the first core die has a greater thickness than that of the first passive die.

Example 12 is a method for fabricating a semiconductor device including: depositing a first top metallization layer on a top of a first core die; and depositing a first bottom metallization layer on a bottom of the first core die; depositing a second top metallization layer on a top of the second core die; depositing a second bottom metallization layer on a first portion of a bottom of the second core die; disposing one or more first bumps on a second portion of the bottom of the second core die; coupling the second core die to one or more TSVs of a plurality of TSVs of the first passive die through the one or more bumps.

In Example 13, the subject matter of Example 12 may optionally include: disposing a plurality of second bumps on the second bottom metallization layer; and coupling the second bottom metallization layer to the first top metallization layer through the plurality of second bumps to form a solder layer between the second bottom metallization layer and the first top metallization layer.

In Example 14, the subject matter of Example 13, wherein the coupling the second bottom metallization layer to the first top metallization layer through the plurality of second bumps to form the solder layer between the second bottom metallization layer and the first top metallization includes: merging the plurality of second bumps into the solder layer.

In Example 15, the subject matter of Example 13 or 14 may optionally include that the plurality of second bumps have at least one of (i) a wider pitch, (ii) a larger diameter, (iii) a greater protrusion height or (iv) a higher solder volume than the plurality of bumps.

In Example 16, the subject matter of any one of Examples 12-15 may optionally include that disposing each of the plurality of second bumps on the second bottom metallization layer includes: disposing a pillar on the second bottom metallization layer and a solder tip extending away from the pillar.

In Example 17, the subject matter of Example 16 may optionally include that the pillar and the solder tip are made of one of (i) a single metal and (ii) a single alloy.

In Example 18, the subject matter of any one of Examples 12-17 may optionally include: disposing a plurality of first bumps on a bottom of the second passive die; and coupling the plurality of second TSVs to the plurality of TSVs other than the one or more TSVs through the plurality of first bumps.

In Example 19, the subject matter of Example 18 may optionally include: depositing a third top metallization layer on a top of a third core die; depositing a third bottom metallization layer on a first portion of a bottom of the third core die; disposing one or more third bumps on a second portion of the bottom of the third core die and the third passive die; disposing a plurality of fourth bumps on the third bottom metallization layer; and coupling the third core die to one or more second TSVs of the second passive die through the plurality of third bumps.

In Example 20, the subject matter of Example 19 may optionally include coupling the third bottom metallization layer to the second top metallization layer through the plurality of fourth bumps to form a second solder layer between the third bottom metallization layer and the second top metallization layer.

In Example 21, the subject matter of any one of Examples 12-20 may optionally include that one or more metallization layers among the first top metallization layer, the first bottom metallization layer, the second top metallization layer and the second bottom metallization layer are made of one of (i) metals or (ii) composite materials.

In Example 22, the subject matter of any one of Examples 12-21 may optionally include that the first core die has a greater thickness than that of the first passive die.

In Example 23, the subject matter of any one of Examples 12-22 may optionally include that depositing each of the first and second top metallization layers on a respective top of a respective core die include: grinding the respective top of the respective core dies prior to depositing the each of the first and second top metallization layers.

While this specification contains many details, these should not be understood as limitations on the scope of what may be claimed, but rather as descriptions of features specific to particular examples. Certain features that are described in this specification or shown in the drawings in the context of separate aspects can also be combined. Conversely, various features that are described or shown in the context of a single aspect can also be implemented in multiple aspects separately or in any suitable sub-combination.

Similarly, while steps/operations of the methods as described above are depicted in a particular order (e.g. as shown in the drawings), this should not be understood as requiring that such operations/steps be performed in the particular order shown or in sequential order, or that all illustrated operations be performed, to achieve desirable results. In certain circumstances, multitasking and parallel processing may be advantageous. For example, some operations/steps may occur in different orders and/or concurrently with other operations/steps apart from those illustrated and/or described herein. In addition, not all illustrated operations/steps may be required to implement one or more aspects or aspects described herein. Also, one or more of the steps depicted herein may be carried out in one or more separate acts and/or phases.

Moreover, the separation/integration of various system components in the aspects described above should not be understood as requiring such separation/integration in all aspects, and it should be understood that the described program components and systems can generally be integrated together in a single product or separated into multiple products.

A number of aspects have been described. Nevertheless, it will be understood that various modifications can be made. Accordingly, other aspects are within the scope of the following claims.

1. A semiconductor device comprising:
a first passive die and a first core die arranged side-by-side laterally in a first tier, wherein the first passive die comprises a plurality of through-silicon vias (TSVs) and the first core die comprises a first top metallization layer deposited on a top of the first core die and a first bottom metallization layer deposited on a bottom of the first core die;
a second core die arranged in a second tier vertically on the first tier, wherein the second core die comprises a second top metallization layer deposited on a top of the second core die and a second bottom metallization layer deposited on a first portion of a bottom of the second core die; and
one or more first bumps disposed between a second portion of the bottom of the second core die and a top of the first passive die, the one or more first bumps configured to couple the second core die to one or more TSVs of the plurality of TSVs of the first passive die.

2. The semiconductor device of claim 1, further comprising a solder layer formed between the second bottom metallization layer and the first top metallization layer.

3. The semiconductor device of claim 2, wherein the solder layer comprises a plurality of second bumps configured to couple the second bottom metallization layer to the first top metallization layer.

4. The semiconductor device of claim 3, wherein the plurality of second bumps have at least one of (i) a wider pitch, (ii) a larger diameter, (iii) a greater protrusion height or (iv) a higher solder volume than the respective plurality of first bumps.

5. The semiconductor device of claim 3, wherein each of the plurality of second bumps comprises a pillar and a solder tip, the pillar disposed on the second bottom metallization layer and the solder tip extending away from the pillar.

6. The semiconductor device of claim 5, wherein the pillar and the solder tip are made of one of (i) a single metal or (ii) a single alloy.

7. The semiconductor device of claim 1, further comprising:
a second passive die arranged side-by side laterally with the second core die in the second tier, wherein the second passive die comprises a plurality of second TSVs; and
a plurality of the first bumps disposed between a bottom of the second passive die and the top of the first passive die, the plurality of the first bumps configured to couple the plurality of second TSVs to the plurality of TSVs of the first passive die other than the one or more TSVs.

8. The semiconductor device of claim 7, further comprising:
a third core die arranged in a third tier vertically on the second tier, wherein the third core die comprises a third top metallization layer deposited on a top of the third core die and a third bottom metallization layer deposited on a first portion of a bottom of the third core die; and
one or more third bumps disposed on a second portion of the bottom of the third core die, the one or more third bumps configured to couple the third core die to one or more second TSVs of the plurality of second TSVs of the second passive die.

9. The semiconductor device of claim 8, further comprising:
a second solder layer formed between the third bottom metallization layer and the second top metallization layer.

10. The semiconductor device of claim 1, wherein one or more metallization layers among the first top metallization layer, the first bottom metallization layer, the second top metallization layer or the second bottom metallization layer are made of one of (i) metals or (ii) composite materials.

11. The semiconductor device of claim 1, wherein the first core die has a greater thickness than that of the first passive die.

12. A method for fabricating a semiconductor device comprising:
depositing a first top metallization layer on a top of a first core die; and
depositing a first bottom metallization layer on a bottom of the first core die;
depositing a second top metallization layer on a top of the second core die;
depositing a second bottom metallization layer on a first portion of a bottom of the second core die;
disposing one or more first bumps on a second portion of the bottom of the second core die; and
coupling the second core die to one or more TSVs of a plurality of TSVs of the first passive die through the one or more first bumps.

13. The method of claim 12, further comprising:
disposing a plurality of second bumps on the second bottom metallization layer; and
coupling the second bottom metallization layer to the first top metallization layer through the plurality of second bumps to form a solder layer between the second bottom metallization layer and the first top metallization layer.

14. The method of claim 13, wherein the coupling the second bottom metallization layer to the first top metallization layer through the plurality of second bumps to form the solder layer between the second bottom metallization layer and the first top metallization comprises:
merging the plurality of second bumps into the solder layer.

15. The method of claim 12, wherein the plurality of second bumps have at least one of (i) a wider pitch, (ii) a larger diameter, (iii) a greater protrusion height or (iv) a higher solder volume than the plurality of bumps.

16. The method of claim 12, wherein disposing each of the plurality of second bumps on the second bottom metallization layer comprises:
disposing a pillar on the second bottom metallization layer and a solder tip extending away from the pillar.

17. The method of claim 16, wherein the pillar and the solder tip are made of one of (i) a single metal or (ii) a single alloy.

18. The method of claim 12, further comprising:
disposing a plurality of the first bumps on a bottom of a second passive die; and
coupling a plurality of second TSVs of the second passive die to the plurality of TSVs other than the one or more TSVs through the plurality of the first bumps.

19. The method of claim 18, further comprising:
depositing a third top metallization layer on a top of a third core die;
depositing a third bottom metallization layer on a first portion of a bottom of the third core die;
disposing one or more third bumps on a second portion of the bottom of the third core die and a plurality of the third bumps on the third passive die;
disposing a plurality of fourth bumps on the third bottom metallization layer; and
coupling the third core die to one or more second TSVs of the second passive die through the plurality of the third bumps.

20. The method of claim 19, further comprising:
coupling the third bottom metallization layer to the second top metallization layer through the plurality of fourth bumps to form a second solder layer between the third bottom metallization layer and the second top metallization layer.
